(19) United States
(12) Patent Application Publication
(10) Pub. No.: US 2015/0347800 A1
(43) Pub. Date: Dec. 3, 2015

(54) POWER SUPPLY TAP

(71) Applicant: FUJITSU COMPONENT LIMITED, Tokyo (JP)

(72) Inventor: Mitsuru KOBAYASHI, Tokyo (JP)

(73) Assignee: FUJITSU COMPONENT LIMITED, Tokyo (JP)

(21) Appl. No.: 14/725,217

(22) Filed: May 29, 2015

(30) Foreign Application Priority Data
Jun. 3, 2014 (JP) 2014-115244

(51) Int. Cl. G06K 7/12; G01R 22/06

(52) U.S. Cl. CPC G06K 7/12; G01R 22/06

(57) ABSTRACT

A power supply tap includes: a reading sensor that is provided near an outlet, and reads a color recorded in a color plate; a converter that converts the color read by the reading sensor into corresponding information; a measurer that measures a power consumption value of an electronics device connected to the outlet in which the color plate is read; and a transmitter that transmits the measured power consumption value and the converted information to a management device managing the power consumption value of the electronics device.

### CROSS-REFERENCE TO RELATED APPLICATION

This application is based upon and claims the benefit of priority of the prior Japanese Patent Application No. 2014-115244 filed on Jun. 3, 2014, the entire contents of which are incorporated herein by reference.

### FIELD

A certain aspect of the embodiments is related to a power supply tap.

### BACKGROUND

Conventionally, there has been known a system in which an identifier (e.g. a bar code or a RFID (Radio Frequency IDentifier) chip) is mounted on an electric plug, a power outlet reads the identifier and a power profiling system performs power supply control (e.g. see Japanese National Publication of International Patent Application No. 2008-522563). Moreover, there has been known a system in which an ID tag is mounted on a power supply plug, data acquired with an outlet is transmitted to a home gateway and energization information of the outlet is managed (e.g. see Japanese Laid-open Patent Publication No. 2008-270075).

In addition, there has been known a system which superimposes on a power supply line an identifying signal from an apparatus inserting a plug by using so-called PLC (Power Line Communication), and transmits information on the apparatus to a power supply tap.

### SUMMARY

According to an aspect of the present invention, there is provided a power supply tap including: a reading sensor that is provided near an outlet, and reads a color recorded in a color plate; a converter that converts the color read by the reading sensor into corresponding information; a measurer that measures a power consumption value of an electronics device connected to the outlet in which the color plate is read; and a transmitter that transmits the measured power consumption value and the converted information to a management device managing the power consumption value of the electronics device.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a system including a power supply tap according to a present embodiment;

FIG. 2 is a schematic diagram illustrating a configuration of the power supply tap;

FIG. 3 is a schematic diagram illustrating a configuration of a variation example of the power supply tap;

FIG. 4A is a diagram illustrating configurations of reading sensors which the power supply tap of FIG. 2 includes;

FIG. 4B is a diagram illustrating configurations of reading sensors which the power supply tap of FIG. 3 includes;

FIGS. 5A and 5B are diagrams illustrating an arrangement relation between a color plate and the reading sensors;

FIGS. 6A to 6C are diagrams illustrating examples of a color plate;

FIGS. 7A and 7B are diagrams illustrating arrangement relations between the color plate and the reading sensor;

FIG. 7C is a diagram illustrating a configuration near outlet insertion slot in the case of FIG. 7A;

FIG. 7D is a diagram illustrating a configuration near outlet insertion slot in the case of FIG. 7B;

FIG. 8 is a flowchart illustrating a reading process of the color plate;

FIGS. 9A and 9B are flowcharts illustrating a readout process of colors in step S3 of FIG. 8;

FIG. 10 is a block diagram illustrating a configuration of a PC or a gateway;

FIG. 11 is a flowchart illustrating the operation of the PC or the gateway and the operation of the power supply tap;

FIG. 12 is a flowchart illustrating a variation example of the operation of the PC or the gateway and the operation of the power supply tap; and

FIG. 13 is a flowchart illustrating the operation of the power supply tap in accordance with contents of the color plate.

### DESCRIPTION OF EMBODIMENTS

In the technique of Japanese National Publication of International Patent Application No. 2008-522563 and Japanese Laid-open Patent Publication No. 2008-270075, a reading circuit for the bar code or the RFID needs to be provided to the power supply tap. In the system using the PLC, PLC devices need to be provided to an AC outlet and the power supply tap. Therefore, in the above-mentioned technique and the system using the PLC, the power supply tap increases in size and the manufacturing cost of the power supply tap increases.

A description will now be given of a present embodiment with reference to the drawings.

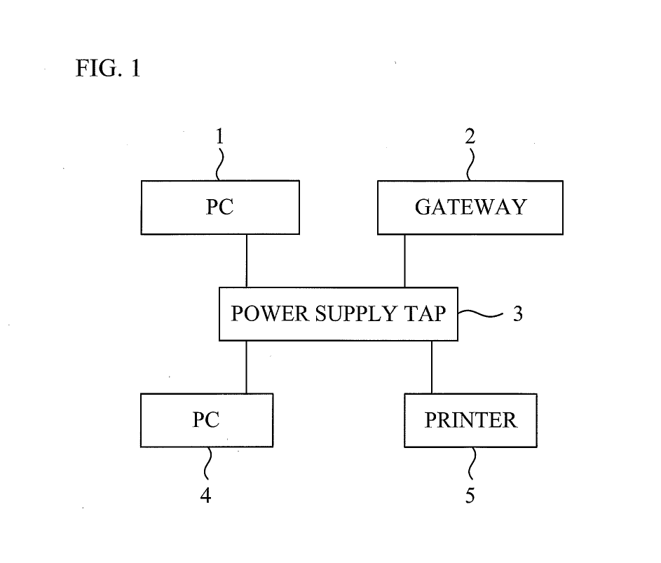

FIG. 1 is a diagram illustrating a configuration of a system including a power supply tap according to a present embodiment.

A plug of an electronics device is connected to a power supply tap 3 illustrated in FIG. 1. In an example of FIG. 1, a PC (Personal Computer) 1 and a printer 5 are connected to the power supply tap 3. The PC1 and a gateway 2 as management devices are communicatably connected to the power supply tap 3, receive information transmitted from the power supply tap 3, and manage the information. The information transmitted from the power supply tap 3 is information indicating each insertion slot of the power supply tap 3, an identifier of a device connected to a corresponding insertion slot, a power consumption value of the device connected to the corresponding insertion slot, an energization period, an energization start time, or an energization end time, for example.

Moreover, each of the PC 1 and the gateway 2 includes software for managing information transmitted from the power supply tap 3. Here, although the system of FIG. 1 includes both of the PC 1 and the gateway 2, the system does not have to include both of the devices. The system may include at least one of the PC 1 and the gateway 2 or include other type of a device which can function as a management device. The power supply tap 3 supplies a power supply to a PC 4 and the printer 5, and acquires power consumption values of the PC 4 and the printer 5 as electronics devices. Moreover, the power supply tap 3 properly transmits the acquired power consumption values and information read from a color plate described later, to the PC 1 and the gateway 2. The PC 4 and the printer 5 are an example of a power supply destination. Other devices may be connected to the power supply tap 3.

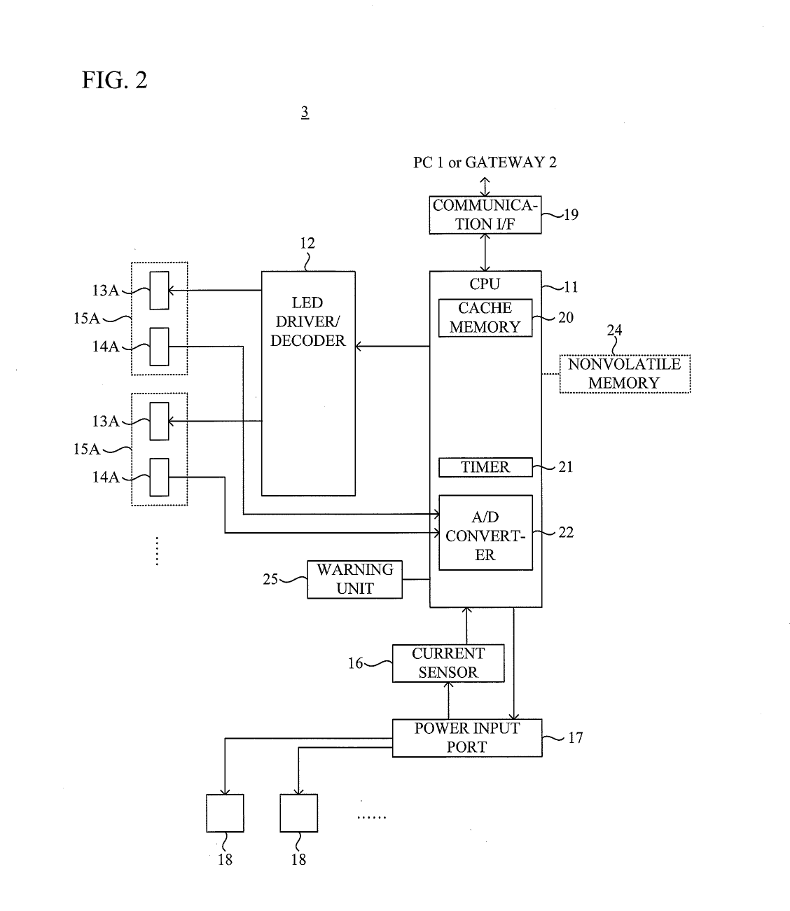

FIG. 2 is a schematic diagram illustrating a configuration of the power supply tap 3.

The power supply tap 3 includes a CPU 11, a LED (Light Emitting Diode) driver/decoder 12, a plurality of full-color LEDs 13A, a plurality of phototransistors 14A, a current sensor 16, a power input port 17 connected to the power supply, not shown, a plurality of outlet insertion slots 18, a communication I/F 19 and a warning unit 25. The power supply tap 3 may include a detachable nonvolatile memory 24. The CPU 11 and the current sensor 16 function as an example of a measurer. The CPU 11 functions as an example of a converter, a controller, and a detector. The CPU 11 and the communication I/F 19 function as a transmitter and a receiver. The outlet insertion slots 18 function as an example of a first insertion slot. The warning unit 25 functions as an example of a warning unit. The CPU 11 includes a cache memory 20, a timer 21 and an A/D converter 22. Data and information stored in the cache memory 20 may be stored in the nonvolatile memory 24.

The CPU 11 controls the whole operation of the power supply tap 3. Moreover, the CPU 11 outputs an LED turn-on signal to the LED driver/decoder 12. The LED turn-on signal includes information indicating the turn-on or the turn-off of the full-color LEDs 13A, and information indicating a color of the full-color LED 13A to be turned on. The LED driver/decoder 12 decodes the LED turn-on signal, and turns on at least one full-color LED 13A to be turned on in a desired color, based on the information indicating the turn-on or the turn-off of the full-color LEDs 13A and the information indicating the color of the full-color LED 13A to be turned on.

A light of the turned-on full-color LED 13A is reflected by the color plate described later, and is read by the phototransistor 14A. The luminance of the light read by the phototransistor 14A is converted into digital data with the A/D converter 22. The CPU 11 judges the color of the color plate from the digital data converted with the A/D converter 22, based on data which associates digital data with a color and is stored in the cache memory 20. The CPU 11 judges information of numerals and letters from the color of the color plate.

The single full-color LED 13A and the single phototransistor 14A constitute a single reading sensor 15A. Therefore, the power supply tap 3 of FIG. 2 includes a plurality of reading sensors 15A. The CPU 11 outputs to the power input port 17 a power supply signal that designates an outlet insertion slot 18 becoming a current supply destination and a power supply stop signal that designates an outlet insertion slot 18 becoming a current supply stop destination. The power input port 17 is connected to the power supply, not shown, and supplies a current from the power supply, not shown, to the outlet insertion slot 18 designated by the power supply signal outputted from the CPU 11. Then, the current sensor 16 measures a current supplied to a device which is connected to the outlet insertion slot 18, and outputs a measured current value to the CPU 11.

Therefore, the CPU 11 can calculate power consumption of the device connected to the outlet insertion slot 18 by receiving a current value from the current sensor 16. As substitute for the current sensor 16, the power supply tap 3 may include a voltage sensor that measures a voltage applied to the outlet insertion slot 18, or a combination of the current sensor and the voltage sensor.

The timer 21 measures a time. When the CPU 11 reads out the energization period, the energization start time or the energization end time from the color plate described later via the phototransistor 14A, for example, the timer 21 is used in order that the CPU 11 outputs the power supply signal or the power supply stop signal to the power input port 17 in accordance with the energization period, the energization start time or the energization end time. When a power consumption value of the device connected to the outlet insertion slot 18 is required from the PC 1 or the gateway 2, the CPU 11 calculates the power consumption value of the device, and transmits the calculated power consumption value and information of the color plate described later to the PC 1 or the gateway 2 via the communication I/F 19. The communication I/F 19 is a LAN port, a USB terminal, a wireless communication terminal or a serial communication terminal (RS-485), for example.

The cache memory 20 stores: data in which colors, and digital data to be converted by the A/D converter 22 are associated with each other; the calculated power consumption value; and data in which colors, and information indicating the colors (e.g. numerals, alphabets and so on) are associated with each other. In addition, the cache memory 20 acquires from the PC 1 or the gateway 2 the information of the color plate registered beforehand with the PC 1 or the gateway 2, and stores the information of the color plate.

The warning unit 25 is composed of a warning lamp, a display or the like. When the information of the color plate acquired from the PC 1 or the gateway 2 is different from the information of the color plate read from the reading sensors 15A or reading sensors 15B described later, the warning unit 25 generates a warning. Specifically, when both of the information of the color plate differ from each other, the warning lamp is tuned on, or information indicating that the acquired information of the color plate and the read information of the color plate differ from each other or the read information of the color plate is abnormal is displayed on the display.

Here, although the CPU 11 controls the turn-on, the turn-off and a luminescence color of the full-color LEDs 13A via the LED driver/decoder 12, the full-color LEDs 13A may be directly connected to the CPU 11 without via the LED driver/decoder 12, and the CPU 11 may directly control the turn-on, the turn-off and a luminescence color of the full-color LEDs 13A. In this case, the LED driver/decoder 12 is unnecessary.

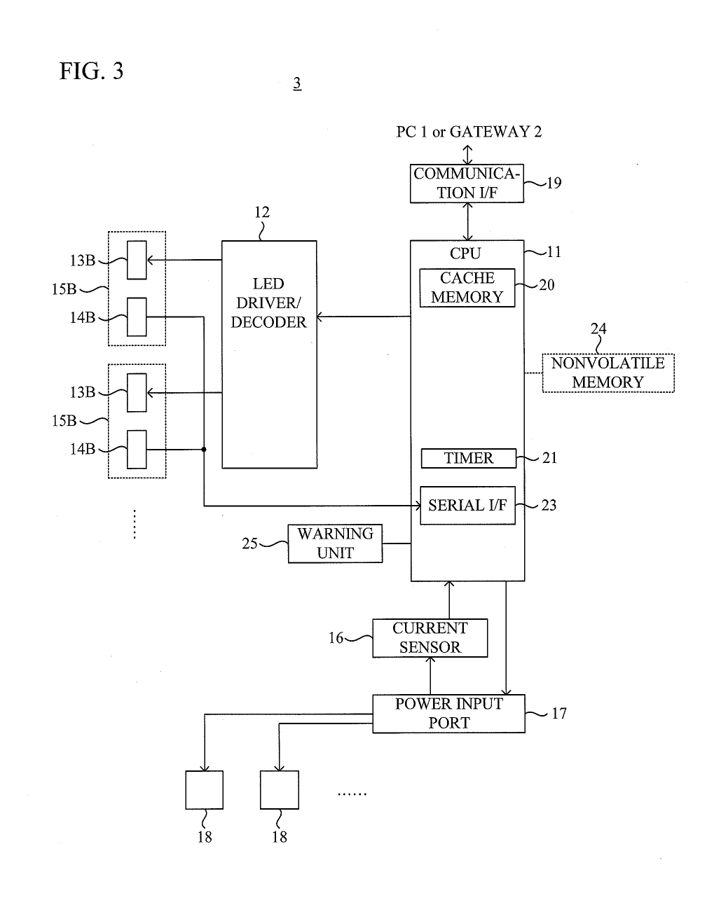

FIG. 3 is a schematic diagram illustrating a configuration of a variation example of the power supply tap 3. Here, a description will be given of only parts different from the power supply tap 3 of FIG. 2.

The power supply tap 3 according to the present embodiment is not limited to the combinations of the full-color LEDs 13A and the phototransistors 14A, as illustrated in FIG. 2. The power supply tap 3 of FIG. 3 includes white LEDs 13B and color sensor modules 14B as substitute for the combinations of the full-color LEDs 13A and the phototransistors 14A. A single reading sensor 15B constitutes a single white LED 13B and a single color sensor module 14B. Therefore, the power supply tap 3 of FIG. 3 includes a plurality of reading sensors 15B. Moreover, the CPU 11 includes a serial I/F 23 that inputs digital data indicating a color read by the color sensor module 14B.

The LED turn-on signal outputted from the CPU 11 includes information indicating the turn-on or the turn-off of the plurality of white LEDs 13B. The LED driver/decoder 12 decodes the LED turn-on signal, and turns on at least one white LED 13B to be turned on, based on the information indicating the turn-on or the turn-off of the plurality of white LEDs 13B.

The light from the turned-on white LED 13B is reflected by the color plate described later, and is received by the color sensor module 14B. The light which the color sensor module 14B receives is converted into digital data indicating the color, and the converted digital data is outputted to the serial I/F 23. The CPU 11 judges the color of the color plate which the color sensor module 14B has read from the digital data inputted to the serial I/F 23, based on the data which is stored in the cache memory 20 and associates the digital data and the colors with each other. The CPU 11 judges the information of the numerals and the letters from the color of the color plate.

Here, although the CPU 11 controls the turn-on and the turn-off of the white LEDs 13B via the LED driver/decoder 12, the CPU 11 may directly control the turn-on and the turn-off of the white LEDs 13B. In this case, the LED driver/decoder 12 is unnecessary.

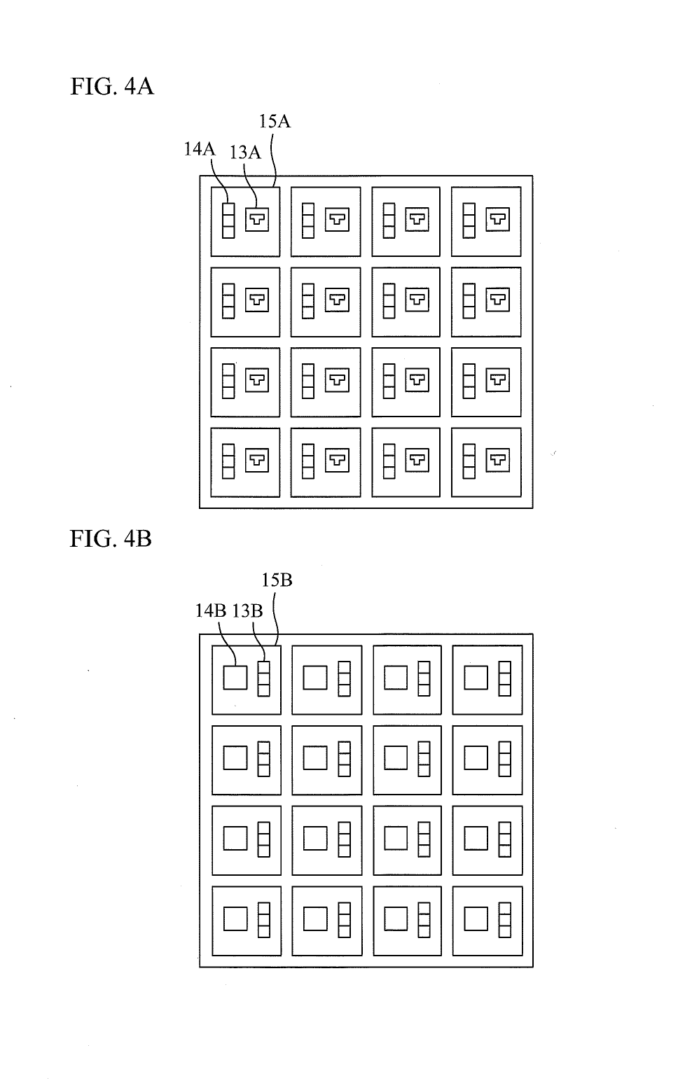

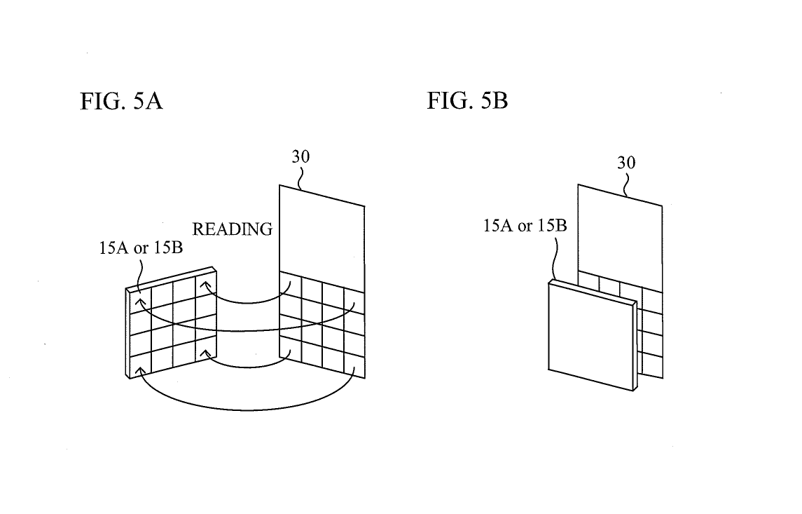

FIG. 4A is a diagram illustrating configurations of the reading sensors 15A which the power supply tap 3 of FIG. 2 includes. FIG. 4B is a diagram illustrating configurations of the reading sensors 15B which the power supply tap 3 of FIG. 3 includes. FIGS. 5A and 5B are diagrams illustrating an arrangement relation between the color plate and the reading sensors 15A and 15B;

The single reading sensor 15A of FIG. 4A includes the single full-color LED 13A and the single phototransistor 14A. The single reading sensor 15B of FIG. 4B includes the single white LED 13B and the single color sensor module 14B. As illustrated in FIGS. 4A and 4B, the power supply tap 3 includes 16 reading sensors 15A or 16 reading sensors 15B. The 16 reading sensors 15A or the 16 reading sensors 15B are arranged in a 4×4 matrix. On the other hand, as illustrated in FIG. 5A, a color plate 30 includes regions which are divided into the 4×4 matrix and where the color is painted individually, and the single reading sensor 15A or the single reading sensor 15B corresponds to any one of the regions and reads the color of a corresponding region. The 16 reading sensors 15A or the 16 reading sensors 15B read the colors of 16 different regions in the color plate 30, respectively.

Moreover, at a reading position of the color plate 30, the 16 reading sensors 15A or the 16 reading sensors 15B are arranged so as to be opposite to the regions in the color plate 30 where the colors are painted, as illustrated in FIG. 5B.

Here, in the case of the reading sensors 15A, the 16 full-color LEDs 13A may emit light at the same time, and the respective corresponding phototransistors 14A may read the reflected light from the color plate 30 at the same time. Alternatively, the 16 full-color LEDs 13A may emit light in turn (e.g. one by one), and the respective corresponding phototransistors 14A may read the reflected light from the color plate 30 in turn.

On the contrary, in the case of the reading sensors 15B, the 16 white LEDs 13B may emit light at the same time, and the respective corresponding color sensor module 14B may read the reflected light from the color plate 30 at the same time. Alternatively, the 16 white LEDs 13B may emit light in turn (e.g. one by one), and the respective corresponding color sensor modules 14B may read the reflected light from the color plate 30 in turn.

The number of reading sensors 15A or 15B included in the power supply tap 3 is 16 in accordance with the number of regions included in the color plate 30 to be read, but the number of reading sensors is not limited to 16. For example, the number of reading sensors 15A or 15B included in the power supply tap 3 may be less than 16 or more than 16 in accordance with the number of regions included in the color plate 30. Moreover, the arrangement of the reading sensors 15A or 15B is not limited to a square matrix form, but may be a rectangular matrix form. For example, 15 reading sensors 15A or 15B may be arranged in a 3×5 matrix. As long as the reading sensors can read and determine the color of each regions in the color plate 30, the reading sensors do not need to be necessarily arranged in a matrix form.

Here, the power supply tap 3 may include the single reading sensor 15A or 15B, and the single reading sensor 15A or 15B may be moved with an actuator and read the colors of the respective regions in the color plate 30. However, when the power supply tap 3 includes the actuator, there is a possibility that the size of power supply tap 3 increases and the manufacturing cost also increases. Moreover, the addition of a driving circuit for the actuator and the positioning accuracy of the reading sensors 15A or 15B must be taken into consideration. It is therefore desirable that the plurality of reading sensors 15A or 15B are arranged in the matrix form, compared with a case where the single reading sensor is moved with the actuator.

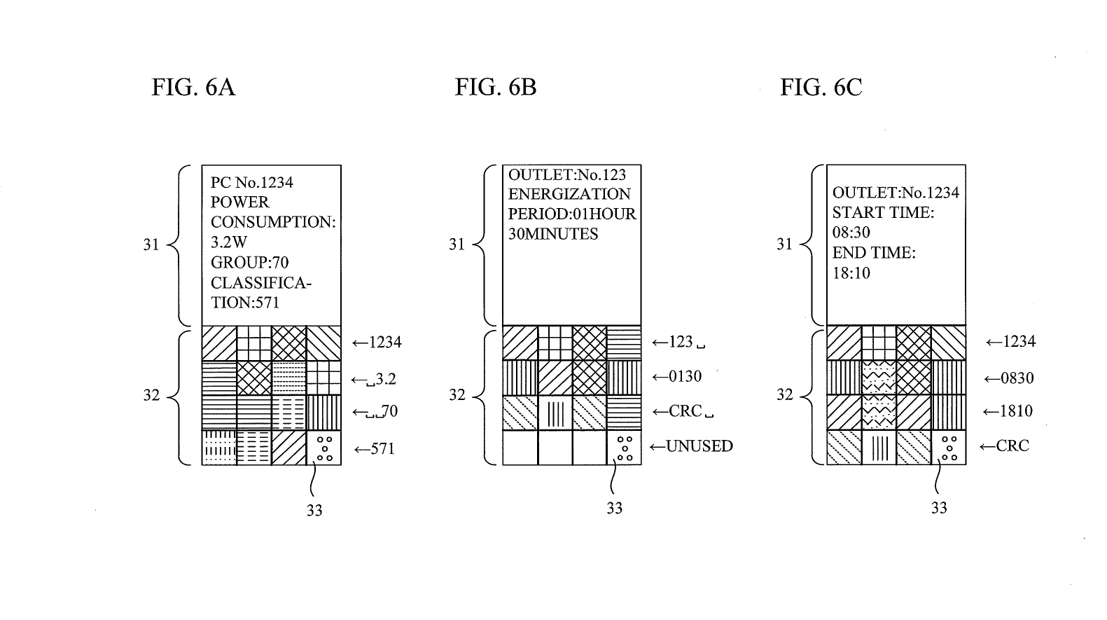

FIGS. 6A to 6C are diagrams illustrating examples of the color plate 30.

The color plate 30 includes a region 31 for writing in information that a person can understand by characters, and a region 32 for painting the colors that the power supply tap 3 recognizes. In the color plate 30 according to the present embodiment, the region 32 is divided into the 4×4 matrix, and a color which means specific information is painted on each divided region. In the color plate 30 according to the present embodiment, different colors are assigned to numerals (0-9), alphabets (A-Z) and marks (a period, a space, a hyphen and so on), respectively. For example, a brown is assigned to a numeral “1”, a red is assigned to a numeral “2”, an orange is assigned to a numeral “3”, a lightest blue is assigned to an alphabet “A”, a blue darker than the alphabet “A” is assigned to an alphabet “B”, and a blue darker than the alphabet “B” is assigned to an alphabet “C”. A corresponding relationship between the information, and the color to be painted on each region needs to be decided optionally.

FIG. 6A illustrates an example in which identification information of a device connected to the outlet insertion slot 18 of the power supply tap 3 is written into the color plate 30. In FIG. 6A, a number of a PC connected to the outlet insertion slot 18 is 1234, a power consumption of the PC is 3.2 W, a group to which the PC belongs is 70, and a classification is 571. These information are written into the region 31 by characters, and the colors corresponding to these information are painted on the region 32. Information to be written into the region 31 and colors to be painted on the region 32 can be freely set by an offerer of the color plate 30.

FIG. 6B illustrates an example in which a number of the outlet insertion slot 18 of the power supply tap 3 and the energization period of the power input port 17 are written into the color plate 30. In FIG. 6B, a number of the outlet insertion slot 18 is 123, and the energization period is 1 hour and 30 minutes. Moreover, a CRC (Cyclic Redundancy Check) code is added to a third line from the top of the region 32. Here, in a last line of the region 32 illustrated in FIG. 6B, no information is recorded on a place other than a region 33 mentioned later. FIG. 6C illustrates an example in which a number of the outlet insertion slot 18 of the power supply tap 3 and the energization start time and the energization end time of the power input port 17 are written into the color plate 30. In FIG. 6C, the number of the outlet insertion slot 18 is 1234, the energization start time is 8:30, and the energization end time is 18:10. Moreover, the CRC code is added to a last line of the region 32.

A given color for detecting existence or nonexistence of the color plate 30 is painted on a given position of the region 32 in the color plate 30. The given color and the given position can be set freely, and the color and the position on which the color for detecting existence or nonexistence of the color plate 30 is painted are stored beforehand into the cache memory 20 of the power supply tap 3. In the examples of FIGS. 6A to 6C, the position and the color of a region used for detecting the existence or nonexistence of the color plate 30 are the region 33 and a gray located on a lower right end of the color plate 30.

Moreover, the CRC code can be added to the region 32 of the color plate 30 by the given color, as illustrated in FIGS. 6B and 6C. Thereby it is possible to detect a reading error of the region 32 of the color plate 30 by the reading sensors 15A or 15B and prevent the forgery of the color plate 30.

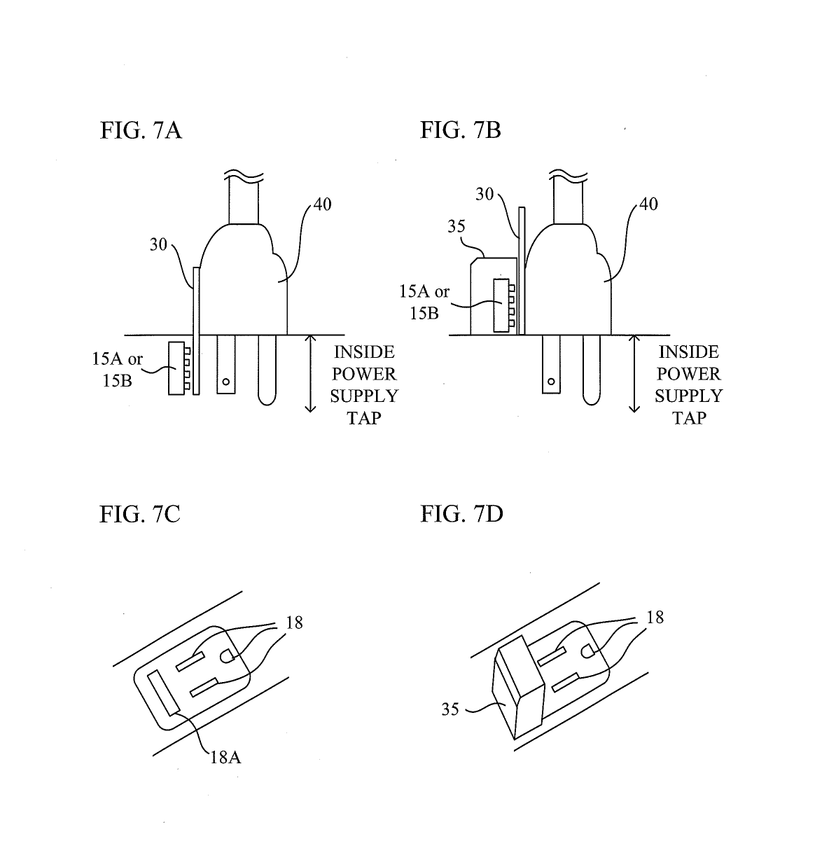

FIGS. 7A and 7B are diagrams illustrating arrangement relations between the color plate 30 and the reading sensors 15A or 15B. FIG. 7C is a diagram illustrating a configuration near the outlet insertion slot 18 in the case of FIG. 7A. FIG. 7D is a diagram illustrating a configuration near the outlet insertion slot 18 in the case of FIG. 7B.

The color plate 30 is placed on a side surface of an AC plug 40 of the PC 4 or the printer 5, as illustrated in FIGS. 7A and 7B. The color plate 30 may be glued on a side surface of the AC plug 40 or separated from the side surface of the AC plug 40. Here, assuming that the color plate 30 is separated from the side surface of the AC plug 40, when the AC plug 40 is inserted into the outlet insertion slot 18, the color plate 30 is placed between the AC plug 40 and the reading sensors 15A or 15B. Assuming that the color plate 30 is separated from the side surface of the AC plug 40, when the AC plug 40 is removed from the outlet insertion slot 18, the color plate 30 is also removed. When the AC plug 40 is inserted into the outlet insertion slot 18, the region 32 of the color plate 30 is placed opposite to the reading sensors 15A or 15B, as illustrated in FIGS. 7A and 7B.

In an example of FIG. 7A, the reading sensors 15A or 15B are placed inside a housing of the power supply tap 3. In this case, a color plate insertion slot 18A that functions as an example of a second insertion slot is provided near the outlet insertion slot 18, as illustrated in FIG. 7C. When the AC plug 40 is inserted into the outlet insertion slot 18, the color plate 30 is also inserted into the color plate insertion slot 18A. On the other hand, in examples of FIGS. 7B and 7D, a reading unit 35 including the reading sensors 15A or 15B is provided on the housing of the power supply tap 3 and near the outlet insertion slot 18. In this case, the reading sensors 15A or 15B is provided on the housing of the power supply tap 3 so as to be exposed to an outside.

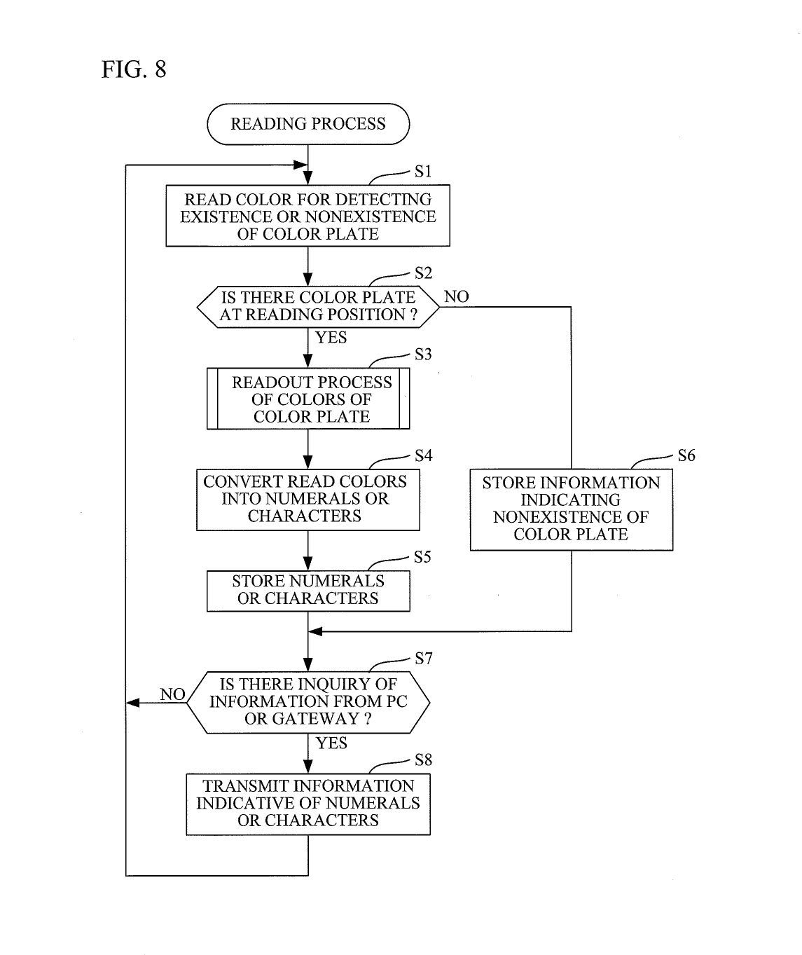

FIG. 8 is a flowchart illustrating a reading process of the color plate.

First, in order to detect the existence or nonexistence of the color plate 30, the reading sensor 15A or 15B reads the painted color on the given position (the region 33 in the example of FIG. 6) (step S1). Next, the CPU 11 determines whether there is the color plate 30 at a reading position of the reading sensor 15A or 15B based on a color for detecting the existence or nonexistence of the color plate 30 stored beforehand in the cache memory 20, and the color read in step S1 (step S2).

When there is the color plate 30 (YES in step S2), the CPU 11 performs a readout process of the colors painted in the region 32 of the color plate 30 (step S3). Specifically, the CPU 11 sequentially reads the colors at the respective positions of the region 32 in the color plate 30 by using the plurality of reading sensors 15A or 15B via the LED driver/decoder 12.

The CPU 11 converts the read colors into information indicative of numerals or characters (step S4), and stores the converted information indicative of numerals or characters into the cache memory 20 (step S5).

When there is no color plate 30 (NO in step S2), the CPU 11 stores information indicating nonexistence of the color plate 30 into the cache memory 20 (step S6).

Next, the CPU 11 determines whether there is an inquiry of the information from the PC 1 or gateway 2 (step S7). When there is the inquiry of the information from the PC 1 or gateway 2 (YES in step S7), the CPU 11 transmits the information indicative of numerals or characters stored into the cache memory 20 to an inquiry source (i.e., the PC 1 or gateway 2) (step S8). The procedure returns to step S1. When there is no inquiry of the information from the PC 1 or gateway 2 (NO in step S7), the CPU 11 transmits no information and the procedure returns to step S1.

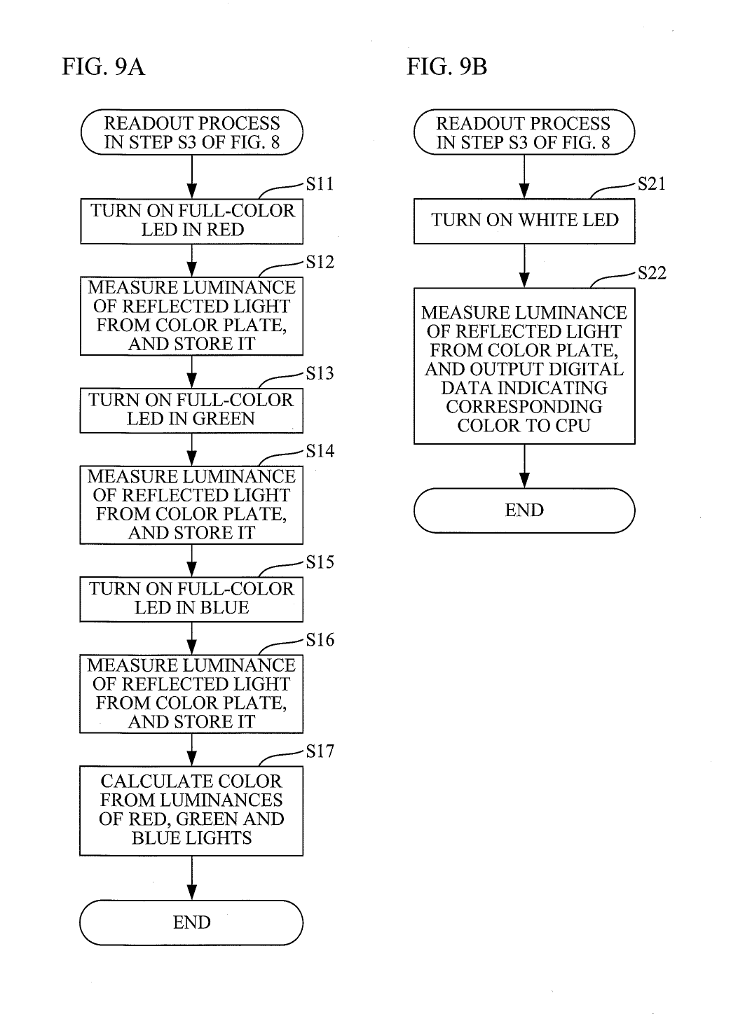

FIGS. 9A and 9B are flowcharts illustrating the readout process of the colors in step S3 of FIG. 8. FIG. 9A corresponds to the readout process of the color by the single reading sensor 15A, and FIG. 9B corresponds to the readout process of the color by the single reading sensor 15B. Since each of the readout processes of the color in FIGS. 9A and 9B illustrates an example in which the color of the color plate 30 is read with the single reading sensor 15A or 15B at a time, it is repeatedly performed in accordance with the number of reading sensors 15A or 15B.

The single full-color LED 13A of the reading sensor 15A can individually emit the light of red, green and blue. In FIG. 9A, the CPU 11 first turns on the full-color LED 13A in red (step S 11), measures the luminance of the reflected light from the color plate 30 using the phototransistor 14A, and stores the luminance of the measured light into the cache memory 20 (step S 12). Here, the measured and stored luminance is a luminance of a red light. Next, the CPU 11 turns on the full-color LED 13A in green (step S 13), measures the luminance of the reflected light from the color plate 30 using the phototransistor 14A, and stores the luminance of the measured light into the cache memory 20 (step S14). In this case, the measured and stored luminance is a luminance of a green light. The CPU 11 turns on the full-color LED 13A in blue (step S15), measures the luminance of the reflected light from the color plate 30 using the phototransistor 14A, and stores the luminance of the measured light into the cache memory 20 (step S16). Here, the measured and stored luminance is a luminance of a blue light. Finally, the CPU 11 calculates a color of the read region from the stored luminances of the red light, the green light and the blue light (step S 17).

The color sensor module 14B includes sensors corresponding to red, green and blue, and each of the sensors outputs a signal in accordance with an amount of the received light of a corresponding color. In FIG. 9B, the CPU 11 turns on the white LED 13B (step S21). The color sensor module 14B measures the luminance of the reflected light from the color plate 30, and outputs digital data corresponding to the luminance of the measured light to the CPU 11 (step S22).

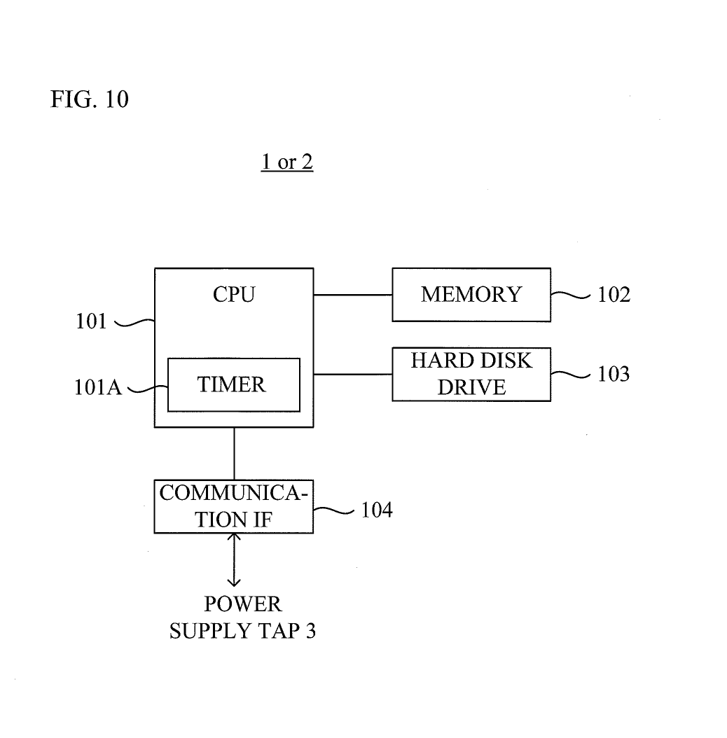

FIG. 10 is a block diagram illustrating the configuration of the PC 1 or the gateway 2.

The PC 1 or the gateway 2 includes: a CPU 101 that controls a whole device; a memory 102 and a hard disk drive 103 that store information of the color plate 30 (e.g. an outlet number, the energization period, and so on), programs, data and so on; and a communication interface (IF) 104. The CPU 101 includes a timer 101A that measures a time. The PC 1 or the gateway 2 is connected to the power supply tap 3 via the communication IF 104. The memory 102 or the hard disk drive 103 stores information acquired from the power supply tap 3 (e.g. the outlet number, the power consumption values of the PC 4 and the printer 5, and the like). Moreover, the memory 102 or the hard disk drive 103 associates, with each other, information acquired from the power supply tap 3, information of a device connected to each outlet insertion slot 18 (e.g. an identification number of the device), and information of each outlet insertion slot 18 (e.g. an identification number of the outlet), and stores the associated information.

The information of the color plate 30 is registered with the memory 102 or the hard disk drive 103 when the information of the color plate 30 is received from the power supply tap 3, as described later, for example. Moreover, the CPU 101 can transmit the information of the color plate 30 registered beforehand with the memory 102 or the hard disk drive 103 (e.g. the outlet number, the energization period, and so on), and various commands to the power supply tap 3 via the communication IF 104.

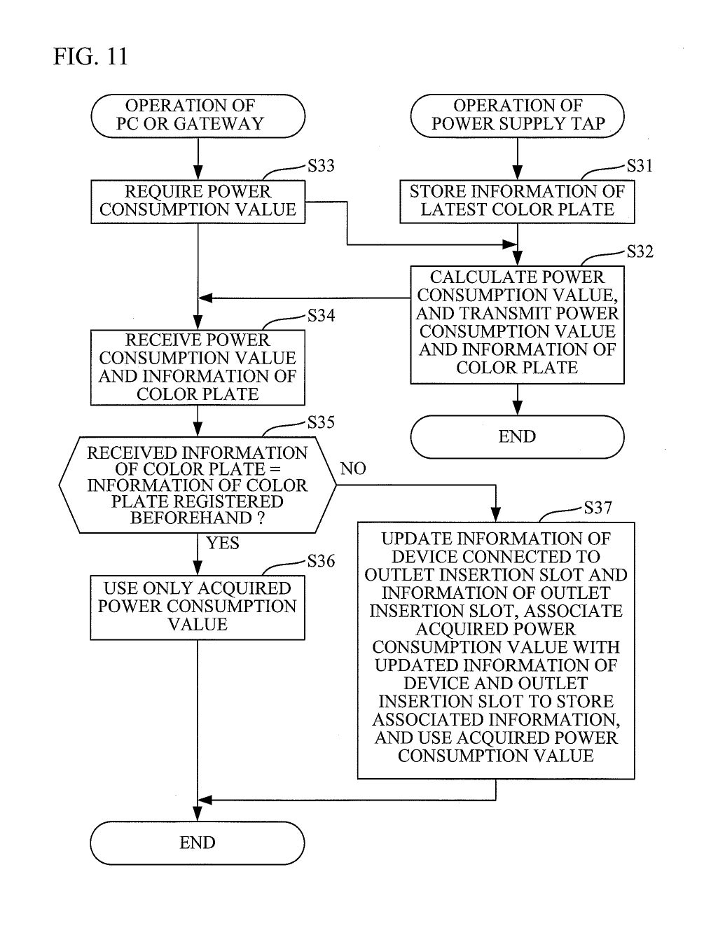

FIG. 11 is a flowchart illustrating the operation of the PC 1 or the gateway 2 and the operation of the power supply tap 3.

First, the CPU 11 of the power supply tap 3 operates the reading sensors 15A or 15B, causes the reading sensors 15A or 15B to read the colors of the color plate 30 corresponding to the AC plug inserted into the outlet insertion slot 18, and stores the information of the read latest color plate 30 into the cache memory 20 (step S31).

When the CPU 101 of the PC 1 or the gateway 2 requires the CPU 11 of a power consumption value of a device connected to the single outlet insertion slot 18 (step S33), the CPU 11 calculates the power consumption value of the device connected to the outlet insertion slot 18, and transmits the calculated power consumption value and the information of the color plate 30 relating to the device stored into the cache memory 20 to the CPU 101 (step S32). The CPU 101 receives the power consumption value and the information of the color plate 30 (step S34).

The CPU 101 determines whether the information of the color plate 30 received from the power supply tap 3 is identical with information of the color plate 30 registered beforehand with the memory 102 or the hard disk drive 103 (step S35).

When the received information of the color plate 30 is not identical with the information of the color plate 30 registered beforehand with the memory 102 or the hard disk drive 103 (NO in step S35), it is considered that the device connected to the outlet insertion slot 18 is changed. In this case, the CPU 101 updates information of the device connected to the outlet insertion slot 18 and information of the outlet insertion slot 18 which are registered with the memory 102 or the hard disk drive 103, by using information of the device connected to the outlet insertion slot 18 (e.g. identification number of the device) and information of the outlet insertion slot 18 (e.g. the identification number) which are included in the received information of the color plate 30, and associates the acquired power consumption value with the updated information of the device and the updated information of the outlet insertion slot 18 to store the associated information (step S37). Thereby, even when the device connected to the outlet insertion slot 18 is changed, the PC 1 or the gateway 2 can identify the device connected to the outlet insertion slot 18 and acquire an accurate power consumption value of the device. Moreover, whenever the device connected to the outlet insertion slot 18 is changed, it is not necessary to change the information of the color plate 30 registered beforehand with the PC 1 or the gateway 2 by manual operation.

On the other hand, when the received information of the color plate 30 is identical with the information of the color plate 30 registered beforehand with the memory 102 or the hard disk drive 103 (YES in step S35), the device connected to the outlet insertion slot 18 is not changed, and hence the CPU 101 uses only the acquired power consumption value (step S36). In this case, since the device connected to the outlet insertion slot 18 is not changed, the information update of step S37 becomes unnecessary.

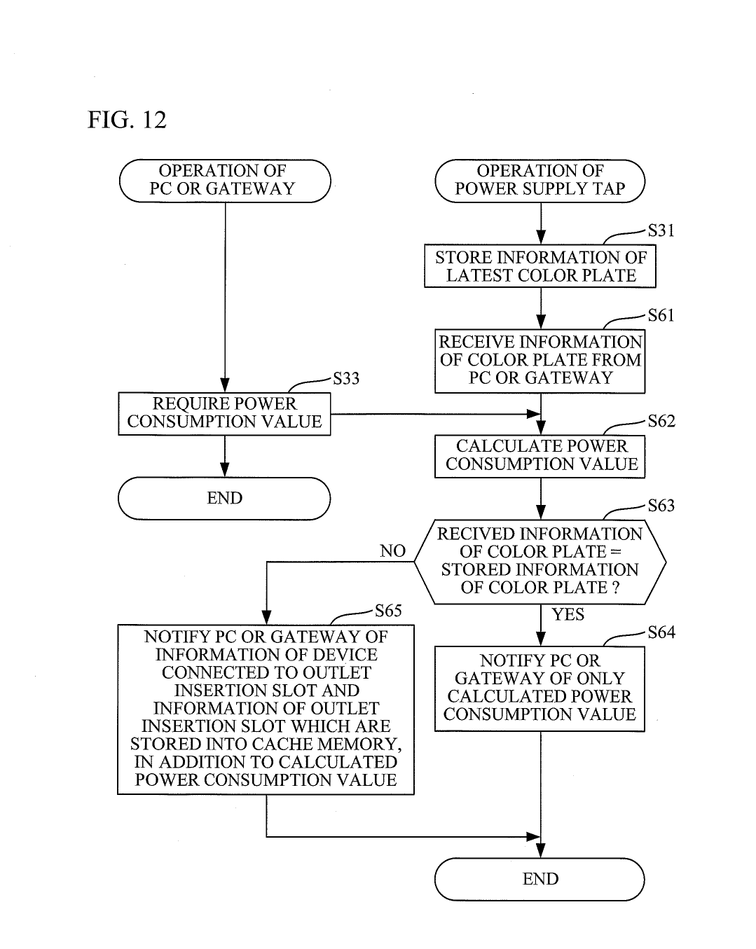

FIG. 12 is a flowchart illustrating a variation example of the operation of the PC 1 or the gateway 2 and the operation of the power supply tap 3. Here, processes which are identical with those of FIG. 11 are designated by identical reference numerals.

First, the CPU 11 of the power supply tap 3 operates the reading sensors 15A or 15B, causes the reading sensors 15A or 15B to read the colors of the color plate 30, and stores the information of the read latest color plate 30 into the cache memory 20 (step S31).

The CPU 11 receives the information of the color plate 30 registered beforehand with the PC 1 or the gateway 2 from the PC 1 or the gateway 2 (step S61). The information of the color plate 30 received from the PC 1 or the gateway 2 is stored into the cache memory 20.

The CPU 101 of the PC 1 or the gateway 2 requires the CPU 11 of the power consumption value of the device connected to the single outlet insertion slot 18 (step S33). The CPU 11 calculates the power consumption value of the device connected to the single outlet insertion slot 18 (step S62).

The CPU 11 determines whether the information of the color plate 30 received from the PC or the gateway in step S61 is identical with the information of the color plate 30 stored into the cache memory 20 (step S63). When the received information of the color plate 30 is not identical with the information of the color plate 30 stored into the cache memory 20 (NO in step S63), the device connected to the outlet insertion slot 18 is changed, and hence the CPU 11 notifies the PC 1 or the gateway 2 of the information of the device (e.g. the identification number of the device) connected to the outlet insertion slot 18 and the information of the outlet insertion slot 18 (e.g. the outlet number) which are stored into the cache memory 20 (i.e., which are read by the reading sensors 15A or 15B), in addition to the power consumption value calculated in step S62 (step S65).

Thereby, the CPU 101 of the PC 1 or the gateway 2 can update the information of the device (e.g. the identification number of the device) connected to the outlet insertion slot 18 and the information of the outlet insertion slot 18 (e.g. the outlet number) which are registered beforehand with the memory 102 or the hard disk drive 103, based on the information notified from the power supply tap, and can use the acquired power consumption value. Thereby, even when the device connected to the outlet insertion slot 18 is changed, the CPU 101 of the PC 1 or the gateway 2 can identify the device connected to the outlet insertion slot 18 and acquire an accurate power consumption value of the device. Moreover, whenever the device connected to the outlet insertion slot 18 is changed, it is not necessary to change the information of the color plate 30 registered beforehand with the PC 1 or the gateway 2 by manual operation.

On the other hand, when the received information of the color plate 30 is identical with the information of the color plate 30 stored into the cache memory 20 (YES in step S63), the device connected to the outlet insertion slot 18 is not changed, and hence the CPU 11 notifies the PC 1 or the gateway 2 of only the calculated power consumption value (step S64). In this case, since the device connected to the outlet insertion slot 18 is not changed, the CPU 11 does not need to notify the PC 1 or the gateway 2 of the information of the device connected to the outlet insertion slot 18 and the information of the outlet insertion slot 18, as indicated in step S65.

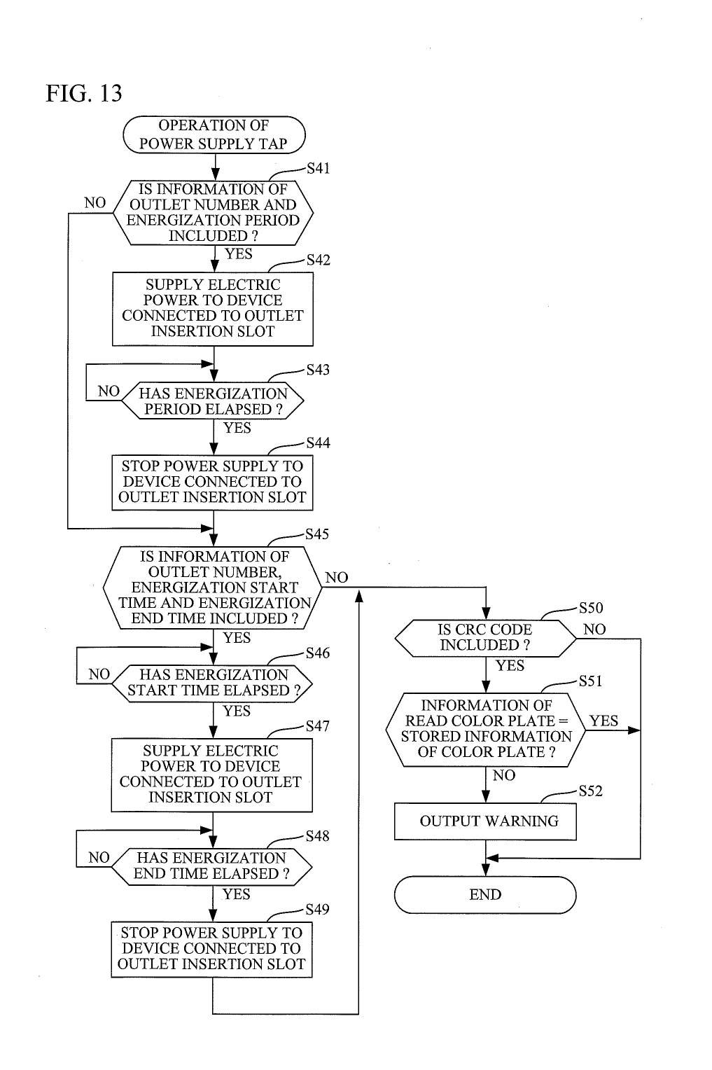

FIG. 13 is a flowchart illustrating the operation of the power supply tap 3 in accordance with contents of the color plate 30. Here, it is assumed that a format of the information written in the color plate 30 is stored beforehand into the cache memory 20. The format of the information written in the color plate 30 indicates what kind of information is written in the color plate 30 in what kind of turn. For example, in the case of the format of the information written in the color plate 30 of FIG. 6B, first four numerals indicate the outlet number, subsequent four numerals indicate the energization period, and further subsequent four numerals indicate the CRC code.

The CPU 11 determines whether information indicative of the outlet number and the energization period is included in the color plate 30, based on the format of the information written in the color plate 30 and the colors read by the reading sensors 15A or 15B (step S41). When the information indicative of the outlet number and the energization period is not included in the color plate 30 (NO in step S41), the procedure advances to step S45. On the other hand, when the information indicative of the outlet number and the energization period is included in the color plate 30 (YES in step S41), the CPU 11 controls the power input port 17 so as to supply an electric power from a power supply, not shown, to a device connected to the outlet insertion slot 18 corresponding to the outlet number (step S42). Thereby, the electric power is supplied to the device connected to the outlet insertion slot 18 corresponding to the outlet number.

The CPU 11 determines whether the energization period read from the color plate 30 has elapsed, based on the time of timer 21 which begins timekeeping from the beginning of the power supply, for example (step S43). When the energization period has not elapsed (NO in step S43), the determination of step S43 is repeated. When the energization period has elapsed (YES in step S43), the CPU 11 controls the power input port 17 so as to stop the power supply to the device connected to the outlet insertion slot 18 corresponding to the outlet number (step S44). Thereby, the power supply to the device is stopped.

The CPU 11 determines whether information indicative of the outlet number, the energization start time and the energization end time is included in the color plate 30, based on the format of the information written in the color plate 30 and the colors read by the reading sensors 15A or 15B (step S45). When the information indicative of the outlet number, the energization start time and the energization end time is not included in the color plate 30 (NO in step S45), the procedure advances to step S50.

When the information indicative of the outlet number, the energization start time and the energization end time is included in the color plate 30 (YES in step S45), the CPU 11 determines whether the energization start time has elapsed, based on the time of the timer 21 (step S46). When the energization start time has not elapsed (NO in step S46), the determination of step S46 is repeated. When the energization start time has elapsed or a current time becomes the energization start time (YES in step S46), the CPU 11 controls the power input port 17 so as to supply the electric power from the power supply, not shown, to the device connected to the outlet insertion slot 18 corresponding to the outlet number (step S47). Thereby, the electric power is supplied to the device connected to the outlet insertion slot 18 corresponding to the outlet number.

After the beginning of the power supply in step S47, the CPU 11 determines whether the energization end time has elapsed, based on the time of the timer 21 (step S48). When the energization end time has not elapsed (NO in step S48), the determination of step S48 is repeated. When the energization end time has elapsed (YES in step S48), the CPU 11 controls the power input port 17 so as to stop the power supply to the device connected to the outlet insertion slot 18 corresponding to the outlet number (step S49). Thereby, the power supply to the device is stopped.

The CPU 11 determines whether the CRC code is included in the color plate 30, based on the format of the information written in the color plate 30 and the colors read by the reading sensors 15A or 15B (step S50). When the CRC code is not included in the color plate 30 (NO in step S50), the present process is completed.

When the CRC code is included in the color plate 30 (YES in step S50), the CPU 11 determines whether the information of the color plate 30 read by the reading sensors 15A or 15B is identical with the information of the color plate 30 stored into the cache memory 20 (step S51). When the information of the color plate 30 read by the reading sensors 15A or 15B is identical with the information of the color plate 30 stored into the cache memory 20 (YES in step S51), the present process is completed. When the information of the color plate 30 read by the reading sensors 15A or 15B is not identical with the information of the color plate 30 stored into the cache memory 20 (NO in step S51), the CPU 11 controls the warning unit 25 so as to generate the warning (step S52). The present process is completed. Thereby, the warning unit 25 can notify a user that the reading sensors 15A or 15B have misread the color plate 30.

As described above, the information indicative of the energization period or the energization start time and the energization end time is written in the color plate 30, and hence it is possible to perform a service which supplies the electric power for a limited period by using the color plate 30. For example, a shop provide a customer with the color plate in which the information indicative of the energization period or the energization start time and the energization end time is written, the customer connects a cell-phone or an information processing terminal to the power supply tap 3, and the reading sensors 15A or 15B read the color plate. Thereby, the customer can charge or use the cell-phone or the information processing terminal only for a period designated by the color plate.

As described above, according to the present embodiment, the reading sensors 15A or 15B which read the color plate 30 are arranged in the matrix form, and hence reading the color plate certainly is achieved. The reading sensors 15A or 15B are arranged in the matrix form, so that a reader for a bar code or a RFID, or a PLC communication device becomes unnecessary for the power supply tap 3. Therefore, the power supply tap 3 can be downsized.

Since the reading sensors can be composed of cheap parts (the full-color LED 13A and the phototransistor 14A, or the white LED 13B and the color sensor module 14B), the manufacturing cost of the power supply tap 3 can be reduced. Moreover, the full-color LED 13A, the phototransistor 14A, the white LED 13B and the color sensor module 14B are directly connected to the CPU 11 of the power supply tap 3. In this case, since exclusive driving circuits for driving the full-color LED 13A, the phototransistor 14A, the white LED 13B and the color sensor module 14B are unnecessary, the power supply tap 3 can be downsized and the manufacturing cost of the power supply tap 3 can be reduced. In addition, since software for controlling the full-color LED 13A, the phototransistor 14A, the white LED 13B and the color sensor module 14B becomes simple, it is not necessary to provide a large number of program memories in the power supply tap 3, the power supply tap 3 can be downsized and the manufacturing cost of the power supply tap 3 can be reduced.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A power supply tap comprising:
a reading sensor that is provided near an outlet, and reads a color recorded in a color plate;
a converter that converts the color read by the reading sensor into corresponding information;
a measurer that measures a power consumption value of an electronics device connected to the outlet in which the color plate is read; and
a transmitter that transmits the measured power consumption value and the converted information to a management device managing the power consumption value of the electronics device.

2. The power supply tap as claimed in claim 1, comprising:
a plurality of reading sensors arranged in a matrix form, each of the reading sensors including a set of a light-emitting unit and a light-receiving unit.

3. The power supply tap as claimed in claim 1, comprising:
a first insertion slot for inserting a plug of the electronics device; and
a reader including the reading sensor;
wherein the reader is placed on a housing of the power supply tap and near the first insertion slot.

4. The power supply tap as claimed in claim 1, comprising:
a second insertion slot into which the color plate is inserted;
wherein the reading sensor is placed opposite to the color plate inserted into the second insertion slot.

5. A power supply tap comprising:
a reading sensor that is provided near an outlet, and reads a color recorded in a color plate;
a converter that converts the color read by the reading sensor into corresponding information; and
a controller that controls power supply from the outlet in which the color plate is read, based on the information converted by the converter.

6. The power supply tap as claimed in claim 5, wherein
when the color plate includes information indicative of an energization period, an energization start time and an energization end time of an electronics device connected to the outlet in which the color plate is read, the controller controls the power supply or stopping the power supply to the electronics device in accordance with the color read by the reading sensor.

7. The power supply tap as claimed in claim 5, comprising:
a receiver that receives information written in the color plate from a management device to which the power supply tap is connected; and
a transmitter that transmits information to the management device;
wherein when the received information written in the color plate is different from information read from the color plate, the transmitter transmits to the management device identification information of an electronics device connected to the outlet in which the color plate is read, and identification information of the outlet into which a plug of the electronics device is inserted.

8. The power supply tap as claimed in claim 7, comprising:
a measurer that measures a power consumption value of the electronics device connected to the outlet in which the color plate is read;
wherein when the received information written in the color plate is different from information read from the color plate, the transmitter transmits the power consumption value measured by the measurer in addition to the identification information of the electronics device and the identification information of the outlet to the management device.

9. The power supply tap as claimed in claim 5, comprising:
a detector that detects existence or nonexistence of the color plate in accordance with a color read from a given position of the color plate.
